(19) United States
(12) Patent Application Publication
(10) Pub. No.: US 2024/0170520 A1
(43) Pub. Date: May 23, 2024

(54) IMAGE SENSOR AND MANUFACTURING METHOD THEREOF

(71) Applicant: SAMSUNG ELECTRONICSCO., LTD., Suwon-si (KR)

(72) Inventors: SUNGCHUL KIM, Suwon-si (KR); UIHUI KWON, Suwon-si (KR); JAE HO KIM, Suwon-si (KR); CHANGYONG UM, Suwon-si (KR)

(21) Appl. No.: 18/215,205

(22) Filed: Jun. 28, 2023

(30) Foreign Application Priority Data
Nov. 17, 2022 (KR) 10-2022-0154816

(51) Int. Cl. H01L 27/146

(52) U.S. Cl. CPC H01L 27/1463; H01L 27/14636; H01L 27/1464; H01L 27/14683

(57) ABSTRACT

An image sensor includes a substrate having a plurality of pixel areas and a pixel isolation structure isolating each of the plurality of pixel areas. The pixel isolation structure includes a deep trench isolation (DTI) area disposed between two adjacent pixel areas among the plurality of pixel areas. An N-type layer is disposed in direct contact with the DTI area and is positioned between the DTI area and the plurality of pixel areas. A P-type layer is disposed in direct contact with the plurality of pixel areas and is positioned between the DTI area and the plurality of pixel areas.

### CROSS-REFERENCE TO RELATED APPLICATION

This application claims priority under 35 U.S.C. § 119 to Korean Patent Application No. 10-2022-0154816, filed on Nov. 17, 2022 in the Korean Intellectual Property Office, the disclosure of which is incorporated by reference in its entirety herein.

### 1. TECHNICAL FIELD

The present disclosure relates to an image sensor and an image sensor manufacturing method.

### 2. DISCUSSION OF RELATED ART

A complementary metal-oxide semiconductor (CMOS) image sensor is an image pickup device manufactured using a CMOS process. The CMOS image sensor includes a plurality of photoelectric conversion elements that form an image pixel array. The CMOS image sensor may include a deep trench isolation (DTI) to distinguish each of the plurality of photoelectric conversion elements. When forming a DTI between the plurality of photoelectric conversion elements, a surface loss of the photoelectric conversion element due to etching occurs. Therefore, a leakage current may occur at an DTI interface due to the surface loss.

A method of applying a negative bias by forming polysilicon on the DTI has been used to overcome this problem. However, the polysilicon formed on the DTI may cause optical sensitivity loss, thereby degrading the signal-to-noise ratio (SNR). SNR degradation is one of the main factors that degrade the quality of an image obtained by an image sensor.

### SUMMARY

Embodiments of the present disclosure provide an image sensor that can increase SNR while blocking a leakage current.

An image sensor according to an embodiment of the present disclosure includes a substrate having a plurality of pixel areas and a pixel isolation structure isolating each of the plurality of pixel areas. The pixel isolation structure includes a deep trench isolation (DTI) area disposed between two adjacent pixel areas among the plurality of pixel areas. An N-type layer is disposed in direct contact with the DTI area and is positioned between the DTI area and the plurality of pixel areas. A P-type layer is disposed in direct contact with the plurality of pixel areas and is positioned between the DTI area and the plurality of pixel areas.

According to an embodiment of the present disclosure, an image sensor includes a substrate having a plurality of pixel areas and a pixel isolation structure isolating each of the plurality of pixel areas. The pixel isolation structure includes a first P-type layer surrounding a first pixel area among the plurality of pixel areas. A second P-type layer surrounds a second pixel area adjacent to the first pixel area in a first direction among the plurality of pixel areas. A first N-type layer and a second N-type layer surround the first and second P-type layers, respectively. A DTI area is disposed between the first N-type layer and the second N-type layer.

According to an embodiment of the present disclosure, an image sensor manufacturing method includes forming a hard mask on a first side of a substrate, and forming a first trench in the substrate through an etching process using the hard mask. A P-type layer is formed by plasma doping (PLAD) a P-type impurity into the first trench. An N-type layer is formed by plasma doping (PLAD) an N-type impurity into the first trench. The hard mask is removed and a DTI area is formed by filling an oxide-based material in the first trench. A photoelectric conversion area is formed by doping a pixel area of the substrate with an N-type impurity.

### BRIEF DESCRIPTION OF THE DRAWINGS

FIG. 1 is a block diagram of an image sensor according to an embodiment of the present disclosure.

FIG. 2 is a circuit diagram of a pixel according to an embodiment of the present disclosure.

FIG. 3 is a top plan view of a portion of the pixel array according to an embodiment of the present disclosure.

FIG. 4 is a cross-sectional view of the pixel array, taken along the line A-A′ of FIG. 3 according to an embodiment of the present disclosure.

FIG. 5 is a top plan view of the bottom surface of the substrate according to an embodiment of the present disclosure.

FIG. 6 is a cross-sectional view of the pixel array, taken along the line B-B′ of FIG. 5 according to an embodiment of the present disclosure.

FIG. 7 is a cross-sectional view of the pixel array, taken along the line C-C′ of FIG. 5 according to an embodiment of the present disclosure.

FIG. 8A to FIG. 8K are cross-section views of the pixel isolation structure and pixel area according to a manufacturing process of the pixel isolation structure according to embodiments of the present disclosure.

FIG. 9 is a top plan view of a portion of a pixel array according to an embodiment of the present disclosure.

FIG. 10 is a block diagram of a computing device according to an embodiment of the present disclosure.

### DETAILED DESCRIPTION OF EMBODIMENTS

Hereinafter, with reference to accompanying drawings, various embodiments of the present disclosure will be described in detail. The present disclosure may be implemented in many different forms and is not necessarily limited to embodiments described herein.

To clearly explain the present disclosure, portions irrelevant to the description may be omitted, and identical or similar constituent elements are given the same reference numerals throughout the specification.

In addition, the size and thickness of each component shown in the drawing may be arbitrarily shown for convenience of explanation. Therefore, embodiments of the present disclosure are not necessarily limited to the drawings. In the drawings, the thickness of layers, films, panels, regions, and the like may be exaggerated for clarity. In addition, in the drawing, for convenience of explanation, the thickness of some layers and regions may be exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “on” in a direction opposite to gravity.

In addition, unless explicitly described to the contrary, the word “comprise”, and variations such as “comprises” or “comprising”, will be understood to imply the inclusion of stated elements but not the exclusion of any other elements.

Further, throughout the specification, when it is referred to as “planar”, it means the case where a target part is viewed from above, and when it is referred to as “in a cross-section”, it means the case where a cross-section obtained by vertically cutting the target part is viewed from the side.

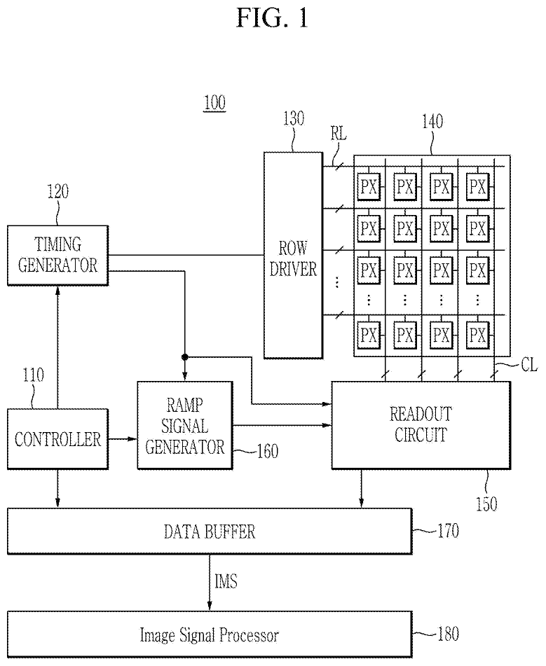

FIG. 1 is a block diagram of an image sensor according to an embodiment.

Referring to FIG. 1, an image sensor 100 according to an embodiment of the present disclosure may include a controller 110, a timing generator 120, a row driver 130, a pixel array 140, a read-out circuit 150, a ramp signal generator 160, a data buffer 170, and an image signal processor 180. In an embodiment, the image signal processor 180 may be disposed outside the image sensor 100.

The image sensor 100 may generate an image signal by converting light received from the outside into an electrical signal. The image signal IMS may be provided to the image signal processor 180.

The image sensor 100 may be mounted on an electronic device having an image or optical sensing function. For example, in an embodiment the image sensor 100 may be mounted on an electronic device such as a camera, a smartphone, a wearable device, an Internet of Things (IoT) device, a home appliance, a tablet personal computer (PC), a personal digital assistant (PDA), a portable multimedia player (PMP), a navigation device, drones, an advanced driver assistance system (ADAS), and the like. Alternatively, the image sensor 100 may be mounted on an electronic device provided as a component in vehicles, furniture, manufacturing facilities, doors, and various measuring devices. However, embodiments of the present disclosure are not necessarily limited thereto and the image sensor 100 may be applied to various other electronic devices.

The controller 110 may control constituent elements included in the image sensor 100, such as the timing generator 120, row driver 130, pixel array 140, read-out circuit 150, ramp signal generator 160 and data buffer 170. The controller 110 may control operation timing of each of the constituent elements using control signals. In an embodiment, the controller 110 may receive a mode signal indicating an imaging mode from an application processor and control the image sensor 100 based on the received mode signal. For example, in an embodiment the application processor may determine the imaging mode of the image sensor 100 according to various scenarios such as illumination of the imaging environment, user's resolution setting, a sensing or learned state, and provide the determined result to the controller 110 as a mode signal. The controller 110 may control a plurality of pixels of the pixel array 140 to output pixel signals according to an imaging mode, and the pixel array 140 may output a pixel signal each of the plurality of pixels or a pixel signal for some of the plurality of pixels, and the read-out circuit 150 may sample and process pixel signals received from the pixel array 140. The timing generator 120 may generate a signal that is a reference for operation timing of components of the image sensor 100. The timing generator 120 may control the timing of the row driver 130, the read-out circuit 150, and the ramp signal generator 160. The timing generator 120 may provide a control signal for controlling the timing of the row driver 130, the read-out circuit 150, and the ramp signal generator 160.

The pixel array 140 may include a plurality of pixels PX, and a plurality of row lines RL and a plurality of column lines CL connected to the plurality of pixels PX, respectively. In an embodiment, each pixel PX may include at least one photoelectric conversion element. The photoelectric conversion element may sense incident light and convert the incident light into an electrical signal according to an amount of light. For example, the photoelectric conversion element may convert the incident light into a plurality of analog pixel signals. In an embodiment, the photoelectric conversion element may be a photodiode or pinned diode. In addition, the photoelectric conversion element may be a single-photon avalanche diode (SPAD) applied to a 3D sensor pixel. A level of an analog pixel signal output from the photoelectric conversion element may be proportional to the amount of charge output from the photoelectric conversion element. For example, the level of the analog pixel signal output from the photoelectric conversion device may be determined according to the amount of light received into the pixel array 140.

A plurality of row lines RL extends in a first direction and may be connected to pixels PXs disposed along the first direction. For example, a control signal output from the row driver 130 to a row line RL may be transmitted to a gate of a transistor of the plurality of pixels PX connected to the corresponding row line RL. The column line CL extends in a second direction crossing the first direction and may be connected to disposed pixels PXs along the second direction. For example, in an embodiment the second direction may be perpendicular to the first direction. However, embodiments of the present disclosure are not necessarily limited thereto. A plurality of pixel signals output from the plurality of pixels PX may be transmitted to the read-out circuit 150 through the plurality of column lines CL.

A color filter layer and microlens layer may be disposed on top of the pixel array 140. The microlens layer includes a plurality of micro lenses, and each of the plurality of microlenses may be disposed over at least one corresponding pixel PX. In an embodiment, the color filter layer includes color filters such as red, green, and blue, and may additionally include a white filter. However, embodiments of the present disclosure are not necessarily limited thereto and the colors of the color filter layer may vary. For one pixel PX, a color filter of one color may be disposed between the pixel PX and a corresponding microlens.

The row driver 130 generates a control signal for driving the pixel array 140 in response to the control signal of the timing generator 120, and transmits the control signal to the plurality of pixels PX of the pixel array 140 through the plurality of row lines RL. In an embodiment, the row driver 130 may control the pixels PX to sense incident light in a row line unit. A row line unit may include at least one row line RL. For example, the row driver 130 may provide a transmission signal TG, a reset signal RG, and a selection signal SEL to the pixel array 140 as will be described later.

The read-out circuit 150 converts the pixel signal (e.g., an electrical signal) from the pixels PX connected to the row line RL selected from among the plurality of pixels PX to a pixel value representing the amount of light in response to the control signal from the timing generator 120. The read-out circuit 150 may convert a pixel signal output through a corresponding column line CL into a pixel value. For example, the read-out circuit 150 may convert a pixel signal into a pixel value by comparing a ramp signal and a pixel signal. The pixel value may be image data having a plurality of bits. In an embodiment, the read-out circuit 150 may include a selector, a plurality of comparators, and a plurality of counter circuits.

The ramp signal generator 160 may generate a reference signal and transmit it to the read-out circuit 150.

The ramp signal generator 160 may include a current source, a resistor, and a capacitor. The ramp signal generator 160 adjusts current intensity of a variable current source or a resistance value of a variable resistor to adjust a ramp voltage, which is a voltage applied to the ramp resistor, to a slope determined according to the current intensity of the variable current source or the resistance value of the variable resistor such that a plurality of falling or rising ramp signals may be generated.

The data buffer 170 stores pixel values of the plurality of pixels PX connected to the selected column line CL transmitted from the read-out circuit 150, and outputs the stored pixel values in response to an enable signal from the controller 110.

The image signal processor 180 may perform image signal processing on the image signal received from the data buffer 170. For example, the image signal processor 180 may receive a plurality of image signals from the data buffer 170 and synthesize the received image signals to generate one image.

In an embodiment, the plurality of pixels may be grouped in the form of M*N in which M and N are integers greater than or equal to 2 to form one unit pixel group. In an embodiment, the M*N form may be a form in which M pixels are arranged in an arrangement direction of the column line CL and N pixels are arranged in the arrangement direction of the row line RL. For example, one unit pixel group may include a plurality of pixels arranged in a 2*2 format, and one unit pixel group may output one analog pixel signal. An embodiment below is not necessarily limited to one pixel and may be applied to a unit pixel group.

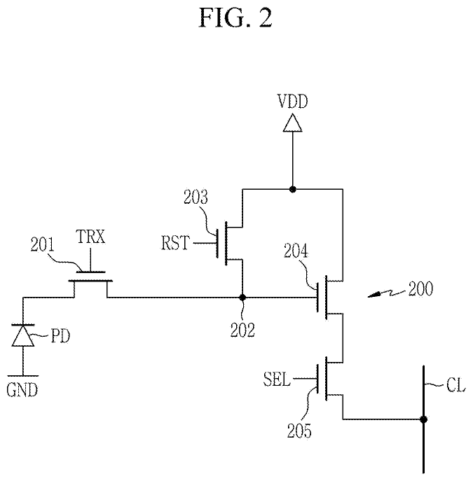

FIG. 2 is a circuit diagram of a pixel according to an embodiment.

In FIG. 2, one pixel circuit of a plurality of sub-pixels of FIG. 1 is illustrated. The pixel circuit 200 according to an embodiment may process charges generated by the photoelectric conversion element PD in response to light and may output an electric signal. A plurality of sub-pixels forming a plurality of pixels PX may be the same as the sub-pixel circuit shown in FIG. 2.

The pixel circuit 200 may include a photoelectric conversion element PD, a transfer transistor 201, a floating diffusion 202, a reset transistor 203, an amplification transistor 204, and a selection transistor 205.

The photoelectric conversion element PD may generate and accumulate charges according to the amount of received light. The photoelectric conversion element PD may include an anode connected to the ground and a cathode connected to one end of the transfer transistor 201. A transfer signal TRX is supplied to a gate of the transfer transistor 201, and the transfer transistor 201 is connected to the floating diffusion 202. When the transfer transistor 201 is turned on by the transfer signal TRX, the charge charged in the photoelectric conversion element PD is transferred to the floating diffusion 202. The floating diffusion 202 may retain charge transferred from the photoelectric conversion element PD.

A reset signal RST is applied to a gate of the reset transistor 203, a voltage VDD is supplied to one end of the reset transistor 203, and the other end of the reset transistor 203 is connected to the floating diffusion 202. When the reset transistor 203 is turned on by the reset signal RST, the floating diffusion 202 may be reset to the voltage VDD. The voltage VDD may be a voltage of a voltage source for driving the pixel circuit.

The amplification transistor 204 may output a pixel signal according to the voltage of the floating diffusion 202. A gate of the amplification transistor 204 is connected to the floating diffusion 202, the voltage VDD is supplied to one end of the amplification transistor 204, and the other end of the amplification transistor 204 is connected to one end of the selection transistor 205. The amplification transistor 204 forms a source follower circuit and may output a voltage at a level corresponding to charge accumulated in the floating diffusion 202 as a pixel signal.

When the selection transistor 205 is turned on by the selection signal SEL, the pixel signal from the amplification transistor 204 may be transferred to the read-out circuit 150 through the column line CL. The selection signal SEL is applied to a gate of the selection transistor 205, and the other end of the selection transistor 205 is connected to the column line CL.

The transfer signal TRX, the selection signal SEL, and the reset signal RST may be supplied from the row driver 130 to each gate of the pixel circuit 200 through the row line RL to which the pixel circuit 200 is connected. The pixel circuit shown in FIG. 2 is an example according to an embodiment, and embodiments of the present disclosure are not necessarily limited thereto. Pixel circuits of various structures may be applied to embodiments of the present disclosure.

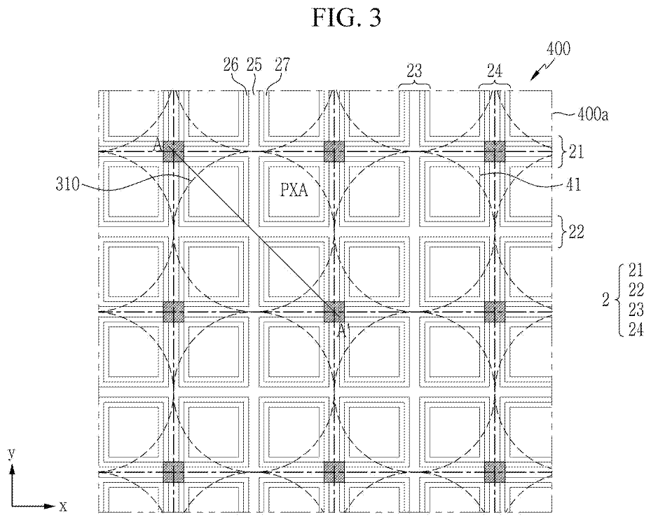

FIG. 3 is a top plan view of a portion of the pixel array according to an embodiment.

In the plan view shown in FIG. 3, a circular dotted line represents a microlens 310 facing an object that is a sensing target of an image sensor in the pixel array 140. In the following description, a position indicated by “upper” may mean closer to the microlens than a position indicated by “lower”. In addition, in FIG. 3, a single-dot chain line represents a color filter positioned at the bottom of the microlens. The embodiment relates to a substrate layer of the pixel array 140, and for a clear description of the substrate layer, the microlens and color filter in FIG. 3 are shown as dotted lines and single-dot chain lines. In FIG. 3, although one microlens 310 is disposed corresponding to four pixel areas PXA, the number of pixels corresponding to one microlens is not necessarily limited thereto. For example, the number of pixels corresponding to one microlens may be one or two in some embodiments.

As shown in FIG. 3, a pixel isolation structure 2 may be formed and disposed in the substrate 400 in a lattice pattern (e.g., in a plan view defined in the x-axis and y-axis directions). The substrate 400 may be divided into a plurality of pixel areas PXA by the pixel isolation structure 2. For example, a pixel area 41 may be disposed in an area defined by a pixel isolation structure area 21 disposed by extending in a first direction (e.g., the x-axis direction in FIG. 3), a pixel isolation structure area 22 that is adjacent to the pixel isolation structure area 21 (e.g., in the y-axis direction) and that extends in the x-axis direction, a pixel isolation structure area 23 disposed by extending in a second direction (e.g., y-axis direction in FIG. 3) that crosses the first direction, and a pixel isolation structure area 24 that is adjacent to the pixel isolation structure area 23 in the x-axis direction and extends in the y-axis direction. A photoelectric conversion area is formed and disposed in the pixel area 41. The photoelectric conversion area is an example in which the photoelectric conversion element PD is implemented in a pixel area.

The pixel isolation structure 2 may include a deep trench isolation (DTI) area 25 formed in a lattice pattern in the substrate 400, a plurality of N-type layer 26 are disposed in direct contact with the DTI area 25 and are positioned between the DTI area 25 and the plurality of pixel areas PXA, and a plurality of P-type layers 27 are disposed in direct contact with the plurality of pixel areas PXA and are positioned between the DTI area 25 and the plurality of pixel areas PXA.

As shown in FIG. 3, each of the plurality of P-type layers 27 surrounds a corresponding pixel area PXA in a flat area on an upper surface 400a of the substrate 400, and each of the plurality of N-type layers 26 surrounds a corresponding P-type layer 27, and the DTI area 25 may be disposed between two adjacent N-type layers 26 surrounding P-type layers 27 of two adjacent pixel areas PXA.

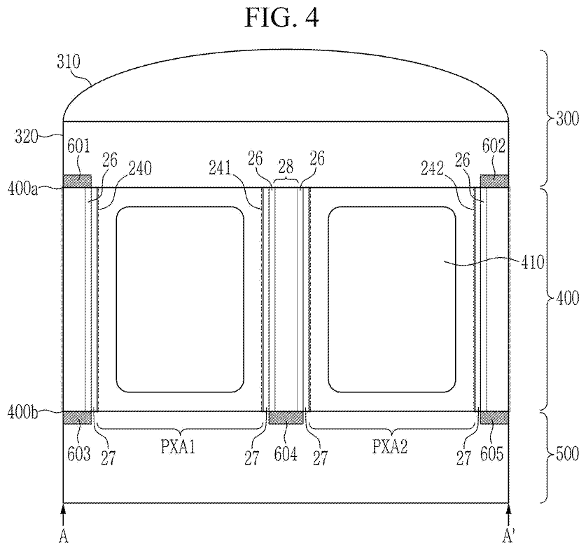

In an embodiment, the DTI area 25 may be formed by filling a deep trench 28 (FIG. 4) formed in the substrate 400 with an oxide-based material. In a plan view, the P-type layer 27 is formed and disposed in a pattern surrounding the external circumferential surface of the pixel area PXA, and the N-type layer 26 is formed and disposed in a pattern surrounding the external circumferential surface of the P-type layer 27. In an embodiment, the N-type layer 26 may be formed of high concentration n-type impurity at an interface of the substrate 400 in direct contact with the DTI area 25. The P-type layer 27 may be formed of high concentration p-type impurity in direct contact with N-type layer 26. In an embodiment, the N-type layer 26 may flow leakage current generated in the DTI area 25, for example, leakage current flowing in the interface between the DTI area 25 and the substrate 400, to a place other than the pixel area. The P-type layer 27 may isolate the pixel area PXA from the N-type layer 26.

FIG. 4 is a cross-sectional view of the pixel array shown in FIG. 3, taken along the line A-A′.

The DTI area 25 may be disposed within the deep trench 28 formed in the substrate 400. The deep trench 28 may be formed as a pattern for separating each of the plurality of pixel areas PXA from the substrate 400. The deep trench 28 is provided for forming the pixel isolation structure 2 shown in FIG. 3, and therefore it may have the same lattice pattern as the shape of pixel isolation structure 2. A depth of the deep trench 28 may be a depth so as to distinguish each pixel area from other adjacent pixel areas. For example, the deep trench 28 may penetrate the substrate 400, or the depth of the deep trench 28 may be close to a depth penetrating the substrate 400.

Referring to FIG. 4, the pixel array 140 may include a light transmission layer 300, the substrate 400, and a wiring layer 500. The light transmission layer 300 may be disposed on an upper surface 400a of the substrate 400, and the wiring layer 500 may be disposed on a bottom surface 400b of the substrate 400. The substrate 400 may include a photoelectric conversion area 410 disposed in a pixel area PXA. Light passing through the light transmission layer 300 may be incident on the photoelectric conversion area 410, and an electrical signal generated by the light incident on the photoelectric conversion area 410 may be transmitted to the read-out circuit 150 through the wiring layer 500.

In an embodiment, an element isolation pattern for separating some of a plurality of components of a pixel circuit may be disposed on the bottom surface 400b of the substrate 400, and at least one gate of the transfer transistor 201 and reset transistor 203 may be disposed on the bottom surface 400b of the substrate 400. A metal layer electrically connected to the N-type layer of pixel isolation structure 2 may be disposed in the light transmission layer 300 and the wiring layer 500. The metal layer may provide a contact for connecting the N-type layer to a predetermined voltage source. For example, in FIG. 4, the metal layer 601 and metal layer 602 are in direct contact with the N-type layer 26 of the pixel isolation structure 2 and are thus electrically connected thereto. The metal layers 601, 602 may be disposed on the light transmission layer 300 on the upper surface 400a of the substrate 400. The metal layers 603, 604, and 605 are in direct contact with the N-type layer 26 of the pixel isolation structure 2 and are thus electrically connected thereto. The metal layers 603, 604 may be disposed within the wiring layer 500 on the bottom surface 400b of the substrate 400.

In an embodiment, the light transmission layer 300 may include a microlens 310 and a color filter 320. The light transmission layer 300 may condense and filter light incident from the outside and provide it to the photoelectric conversion area 410.

The color filter 320 and the microlens 310 may be sequentially disposed on the upper surface 400a of the substrate 400. In an embodiment, the color filter 320 may be a filter that passes at least one of green, red and blue, or cyan, magenta, and yellow. The microlens 310 may condense incident light by being disposed in a convex form on the color filter 320. In FIG. 3 and FIG. 4, it is illustrated that for four pixel PX units of 2*2 structure, the color filter 320 passes the same color, and one microlens 310 is disposed correspondingly. However, embodiments of the present disclosure are not necessarily limited thereto. In an embodiment, an anti-reflection coating and insulation layer may be disposed between the substrate 400 and the color filter 320, and an insulation layer may be disposed between the color filter 320 and the microlens 310.

The substrate 400 may include a photoelectric conversion area 410 and a pixel isolation structure 2. In an embodiment, the substrate 400 may be a semiconductor substrate or a silicon on insulator (SOI) substrate. The semiconductor substrate may include, for example, a silicon substrate, a germanium substrate, or a silicon-germanium substrate. The substrate 400 may include an impurity of the first conductivity type. For example, the impurity of the first conductivity type may include p-type impurity such as aluminum (Al), boron (B), indium (In), and/or gallium (Ga). In FIG. 4, the pixel area PXA disposed on the substrate 400 is separated by the pixel isolation structure 2. For example, a pixel area PXA1 is disposed between a pixel isolation structure area 240 and a pixel isolation structure area 241, and a pixel area PXA2 is disposed between the pixel isolation structure area 241 and a pixel isolation structure area 242 to be separated from other pixel areas.

The pixel area PXA1 may include a photoelectric conversion area 410 forming a photoelectric conversion element. The photoelectric conversion area 410 may generate and accumulate photocharges in proportion to the intensity of incident light. The photoelectric conversion area 410 may be implemented as a region doped with a second conductive type of impurity within the substrate 400. The impurity of the second conductive type may have a conductive type opposite to that of the first conductive type. In an embodiment, the impurity of the second conductive type may include an n-type impurity such as phosphorus, arsenic, bismuth, and/or antimony. The first conductive type impurity area of the substrate 400 and the photoelectric conversion area 450 may form a photodiode with a P-N junction.

The wiring layer 500 may include electrodes and wirings connected to the pixel circuit to transfer the charge accumulated in the photoelectric conversion area 410 to the read-out circuit 150.

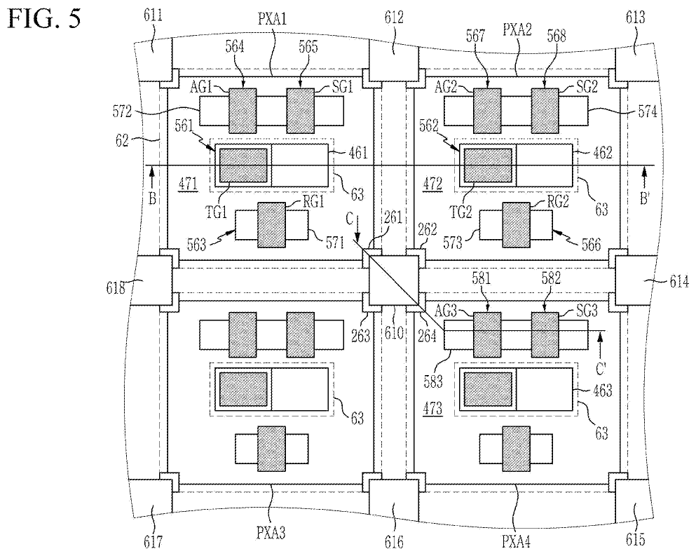

FIG. 5 is a top plan view of the bottom surface of the substrate according to an embodiment.

In FIG. 5, transfer transistors 561 and 562, reset transistors 563 and 566, amplification transistors 564 and 567, selection transistors 565 and 568, and floating diffusions 461 and 462 disposed on the bottom surface 400b of the substrate 400 are illustrated. The bottom surface 400b shown in FIG. 5 is an example for describing an embodiment. However, embodiments of the present disclosure are not necessarily limited thereto. The transfer transistors 561 and 562 include transfer gates TG1 and TG2, and the transfer transistors 561 and 562 may be disposed in direct contact with the floating diffusions 461 and 462, respectively. The reset transistors 563 and 566 include active areas 571 and 573 and reset gates RG1 and RG2 disposed to overlap the active area 571 and 573, respectively. The amplification transistors 564 and 567 include a portion of the active areas 572 and 574 and amplification gates AG1 and AG2 disposed to overlap the portion of the active areas 572 and 574, respectively. The selection transistors 565 and 568 include another portion of the active areas 572 and 574 and selection gates SG1 and SG2 disposed to overlap the other portion of the active areas 572 and 574, respectively. In an embodiment, the active areas 571 to 574 may be formed with a predetermined thickness within the substrate 400 extending from the bottom surface 400b. Each gate may be disposed on the bottom surface 400b corresponding to a corresponding active area, and a gate insulation layer may be disposed between each gate and the active area.

As shown in FIG. 5, each of the plurality of pixel areas PXA1 to PXA4 are separated by the pixel isolation structure 2. The plurality of metal layers 610 to 618 are electrically connected while being in direct contact with the N-type layer 26 of the pixel isolation structure 2 surrounding each of the plurality of pixel areas PXA1 to PXA4. In an embodiment, each of the plurality of metal layers 610 to 618 may be disposed adjacent to each corner area of the corresponding four pixel areas among the plurality of pixel areas PXA1 to PXA4. Each of the plurality of metal layers 610 to 618 may be disposed to directly contact the N-type layer 26 exposed on the bottom surface 400b at each corner area of the four pixel area. Four pixel areas corresponding to each metal layer may be disposed adjacent to each other. For example, the metal layer 610 may be in direct contact with some areas of the N-type layer 26 adjacent to the metal layer 610 and includes some regions exposed on the bottom surface 400b of the substrate which are disposed at four corner areas of each of the four pixel areas PXA1 to PXA4. For example, the N-type layer 26 includes a partial area 261 exposed on the bottom surface 400b in one edge region of the pixel area PXA1, a partial area 262 exposed on the bottom surface 400b in one edge region of pixel area PXA2, a partial area 263 exposed on the bottom surface 400b in one edge region of the pixel area PXA3, and a partial area 264 exposed on the bottom surface 400b in one edge region of the pixel area PXA4. The metal layer 610 may be electrically connected while being in direct contact with the plurality of partial areas 261 to 264.

In FIG. 5, the metal layers 610 to 618 are schematically shown as quadrangle for convenience of description. However, embodiments of the present disclosure are not necessarily limited thereto and the shape of the metal layer 610 to 618 may be implemented in a shape different from the shape shown in FIG. 5. In addition, the plurality of partial areas 261 to 264 schematically shown in FIG. 5 may also be implemented in other shapes. In FIG. 5, the corresponding four metal layers are disposed for each of the four corner areas of the four pixel areas PXA1 to PXA4. However, embodiments of the present disclosure are not necessarily limited thereto. For example, in an embodiment only one metal layer among the four metal layers may be disposed. For example, only the metal layer 610 among the nine metal layers 610 to 618 may be disposed. For example, in an embodiment, for each four pixel area, only one metal layer among the four pixel areas is connected to the N-type layer 26, thereby covering four pixel areas. The resistance to connect the N-type layer 26 to a predetermined voltage source decreases as the number of metal layers increases, and all N-type layer 26 surrounding the plurality of pixel areas needs be connected to a voltage source. The number and the position of the metal layer can be determined in consideration thereof.

In FIG. 5, the dotted line 62 schematically shows an interface of the DTI area 25 and the N-type layer 26 in the pixel isolation structure 2, which is not actually visible in the plan view of the bottom surface 400b. An interface between the P-type layer 27 and the plurality of pixel areas PXA1 to PXA4 will be described later with reference to a cross-sectional view below.

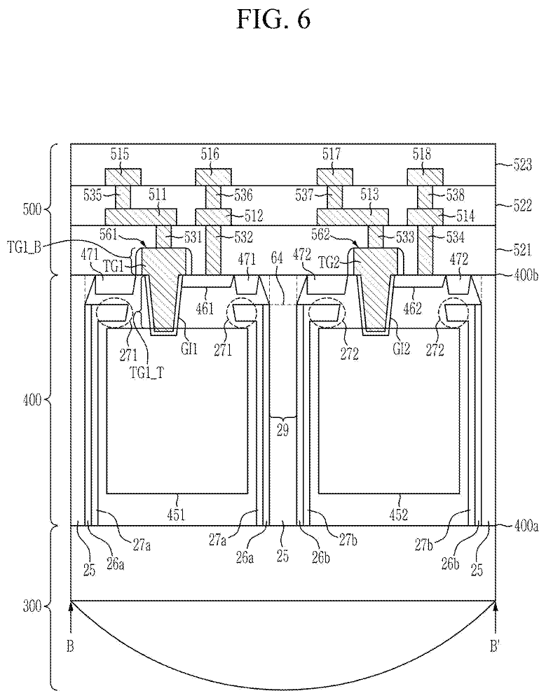

FIG. 6 is a cross-sectional view of the top plan view of FIG. 5, taken along the line B-B′.

For convenience of description, a portion of the wiring layer 500, which is not shown in FIG. 5, is illustrated in the cross-sectional view of FIG. 6. The wiring layer 500 shown in FIG. 6 may be a portion of the entire wiring layer of the image sensor 100.

As shown in FIG. 6, the DTI area 25 of the pixel isolation structure 2 may be disposed in the deep trench 29 formed in the substrate 400. In an embodiment, the deep trench 29 may penetrate the substrate 400, and an oxide-based material may be filled to form the DTI area 25. In an embodiment, in a cross-sectional view, the deep trench 29 may have a shape having a width that increases from a lower boundary 64 of the P-type layer 27a and the N-type layer 26a to the bottom surface 400b.

One side of the N-type layer 26a is disposed in direct contact with the DTI area 25 along a boundary indicated by the dotted line 62 between the bottom surface 400a and the lower boundary 64, and the other side of the N-type layer 26a is disposed in direct contact with the P-type layer 27a between the upper surface 400a and the lower boundary 64. The P-type layer 27a may be disposed between the N-type layer 26a and the photoelectric conversion area 451 between the upper surface 400a and the lower boundary 64. The P-type layers 27a and 27b may include photoelectric conversion areas 451 and 452 and a photodiode between the substrate 400 and photodiode well areas 271 and 272 for separating other devices. The PD well areas 271 and 272 are formed by extending into the pixel area in a direction substantially orthogonal to a depth direction of the substrate 400, and may be disposed between the bottom surface 400b of the substrate 400 and the photoelectric conversion areas 451 and 452. The PD well areas 271 and 272 may not be formed in a channel area formed between the photoelectric conversion area 451 and the floating diffusion 461. In addition, for the transfer gates TG1 and TG2 to provide an on-voltage to the photoelectric conversion area 451, the PD well areas 271 and 272 may not be formed even in a region where the transfer gate TG is disposed. For example, the area surrounded by the dotted line 63 in the pixel areas PXA1 to PXA4 in FIG. 5 indicates an area where a channel between the floating diffusion and the photoelectric conversion area and an area where the transfer gate is disposed. The PD well areas 271 and 272 may be formed over an area except for the area surrounded by the dotted line 63 within each pixel area.

Element isolation patterns 471 and 472 may be provided within the substrate 400 and defined in the bottom surface 400b. For example, shallow trench isolation (STI) to provide the element isolation patterns 471 and 472 may be recessed from the bottom surface 400b in an upper direction. In an embodiment, the element isolation patterns 471 and 472 may be formed by filling the STI with a silicon oxide, a silicon nitride, and/or a silicon oxynitride. In the present disclosure, an upper direction may mean a direction from the bottom surface 400b to the upper surface 400a. The element isolation patterns 471 and 472 may separate transfer transistors 561 and 562, reset transistors 563 and 566, amplification transistors 564 and 567, and selection transistors 565 and 568 within pixel areas PXA1 and PXA2. Active areas 571 to 574 of each transistor may be disposed in regions defined by the element isolation patterns 471 and 472. The floating diffusions 461 and 462 are disposed adjacent to the transfer transistors 561 and 562, and gate insulation layers G11 and G12 are formed and disposed between the transfer gates TG1 and TG2 and the floating diffusions 461 and 462. The transfer gates TG1 and TG2 may extend to the inside of the photoelectric conversion areas 451 and 452. The conversion gates TG1 and TG2 may include a bottom gate TG1_B disposed on the bottom surface 400b and a top gate TG1_T disposed within the substrate 400. As shown in FIG. 6, the top gate TG1-T may be arranged to extend to the photoelectric conversion area 451 and 452.

When an on-voltage is supplied to the transfer gates TG1 and TG2 and a channel is formed between the photoelectric conversion areas 451 and 452 and the floating diffusions 461 and 462, photons accumulated in the photoelectric conversion areas 451 and 452 may be transmitted to the floating diffusions 461 and 462.

The wiring layer 500 may include a plurality of wires 511 to 518, a plurality of line insulation layers 521 to 523, and a plurality of wiring contacts 531 to 538. The line insulation layer 521 is disposed on the bottom surface 400b of the substrate 400 to cover a plurality of gate electrodes (e.g., TG1, TG2, RG1, RG2, AG1, AG2, SG1, SG2) and a plurality of floating diffusions 461, and 462. The plurality of wiring contacts 531 to 534 are formed on a plurality of vias of the line insulation layer 521, and each wiring contact is connected to a corresponding one of the transmission gate TG1, the floating diffusion 461, the transmission gate TG2, and the floating diffusion 462. The plurality of wires 511 to 514 are disposed on the line insulation layer 521, and each of the plurality of wires 511 to 514 is connected to the plurality of wiring contacts 531 to 534 formed on the line insulation layer 521, respectively. The line insulation layer 522 may be disposed on the line insulation layer 521 to cover the plurality of wires 511 to 514. The plurality of wiring contacts 535 to 538 may be formed in a plurality of vias of the line insulation layer 522, and each wire contact may be connected to a corresponding one of the plurality of wires 511 to 514. A plurality of wires 515 to 518 are disposed on the line insulation layer 522, and each of the plurality of wires 515 to 518 is connected to each of a plurality of wiring contacts 535 to 538 formed on the line insulation layer 522. A line insulation layer 523 may be disposed on the line insulation layer 522 to cover the plurality of wires 515 to 518. The wire 515 may be electrically connected to the transfer gate TG1. The wire 516 may be electrically connected to the floating diffusion 461. The wire 517 may be electrically connected to the transfer gate TG2. The wire 518 may be electrically connected to the floating diffusion 462.

In an embodiment, the plurality of line insulation layers 521 to 523 may include a silicon-based insulating material such as a silicon oxide, a silicon nitride, and/or a silicon oxynitride. However, embodiments of the present disclosure are not necessarily limited thereto and the material of the line insulation layers 521 to 523 may vary. Additionally, the number of the plurality of line insulation layers may be greater than three in some embodiments.

The configuration of the wiring layer 500 shown in FIG. 6 is an example to show that each component of the pixel circuit can be connected to other components through wiring. However, embodiments of the present disclosure are not necessarily limited thereto. In an embodiment, the reset transistor, the amplification transistor, and the selection transistor may also be connected to other components through a plurality of wirings included in the wiring layer 500. For example, the floating diffusion 461 may be connected to one end of the reset transistor 563 and a gate of the amplification transistor 564 through the wire 516.

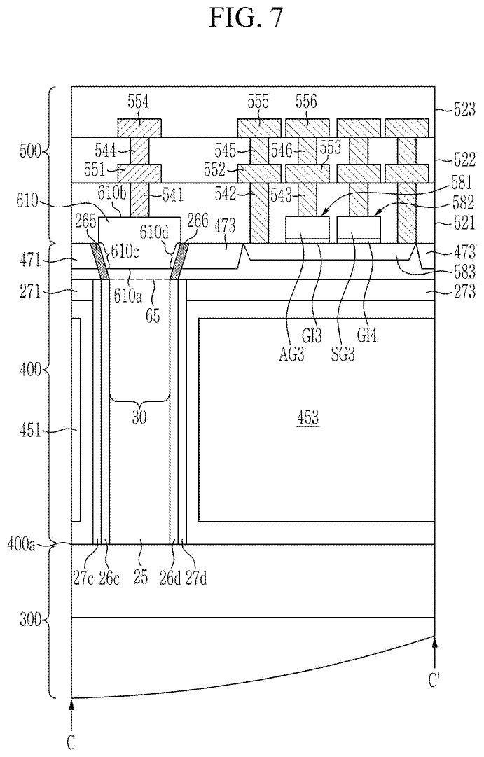

FIG. 7 is a cross-sectional view of the top plan view of FIG. 5, taken along the line C-C′.

For description of an embodiment, a part of the wiring layer 500 shown in FIG. 5 is illustrated in FIG. 7. The wiring layer 500 shown in FIG. 7 may be a part of the entire wiring layer of the image sensor 100.

As shown in FIG. 7, a DTI area 25 of a pixel isolation structure 2 may be disposed in a deep trench 30 formed in the substrate 400. In an embodiment, the deep trench 30 may penetrate the substrate 400, and an oxide-based material may be filled in the deep trench 30 to form the DTI area 25. As shown in FIG. 5, the metal layer 610 may be disposed across the four adjacent corner areas of the adjacent four pixel areas PXA1 to PXA4. In FIG. 7, the metal layer 610 is disposed over the substrate 400 and the wiring layer 500. However, embodiments of the present disclosure are not necessarily limited thereto, and the metal layer 610 may be implemented in various shapes exposed on the substrate 400 and electrically connected to N-type layers 26c and 26d.

The upper surface 610a of the metal layer 610 is in direct contact with the DTI area 25 within the deep trench 30, and some areas 610c and 610d (e.g., some portions) on the side of the metal layer 610 are in direct contact with contact areas 265 and 266 of the N-type layers 26c and 26d, and a bottom surface 610b of the metal layer 610 is connected to a wiring contact 541 formed in a via provided in the line insulation layer 521.

One surface (e.g., a first surface) of the N-type layers 26c and 26d may include a region in direct contact with the DTI area 25, and the other surface (e.g., an opposite second surface) of N-type layers 26c and 26d may include a region disposed in direct contact with P-type layer 27c and 27d. For example, in an area between the upper surface 400a and a lower boundary 65, one side of the N-type layers 26c and 26d includes an area in direct contact with the DTI area 25, and the other side of the N-type layers 26c and 26d may include an area disposed in direct contact with P-type layers 27c and 27d. The contact area 265 and 266 may be provided for electrical connection between the N-type layers 26c and 26d and the metal layer 610. For example, the contact area 265 of the N-type layer 26c may be arranged to extend to the bottom surface 400b while directly contacting a portion of the area 610c of a side surface of the metal layer 610. The contact area 266 of the N-type layer 26d may be arranged to extend to the bottom surface 400b while directly contacting a portion of the area 610d of the side surface of the metal layer 610. The contact area 265 is a contact area of the N-type layer 26c disposed in the pixel area PXA1, and the contact area 266 is a contact area of the N-type layer 26d disposed in the pixel area PXA4. The contact area 265 may be separated from other components by an element isolation pattern 471 disposed in direct contact with each other, and the contact area 266 may be separated from other components by an element isolation pattern 473 disposed in direct contact with each other. In an embodiment, the contact areas 265 and 266 may provide ohmic contact between the N-type layers 26c and 26d and the metal layer 610.

The P-type layers 27c and 27d may be disposed between the N-type layers 26c and 26d and the photoelectric conversion areas 451 and 453, respectively, in the area between the upper surface 400a and the lower boundary 65. The P-type layers 27c and 27d may include PD well areas 271 and 273 for separating photoelectric conversion areas 451 and 453 from other devices on the substrate 400. In FIG. 5, no channel is formed in the area along the C-C′ line in the cross-section diagram of FIG. 7, the PD well areas 271 and 273 are shown as shapes extending in a direction substantially orthogonal to a depth direction of the substrate 400 to cover all of the photoelectric conversion areas 451 and 453.

The element isolation patterns 471 and 473 may be recessed in an upper direction from the bottom surface 400b in an STI structure. In an embodiment, the element isolation patterns 471 and 473 may include a silicon oxide, a silicon nitride, and/or a silicon oxynitride. However, embodiments of the present disclosure are not necessarily limited thereto.

An active area 583 of an amplification transistor 581 and a selection transistor 582 may be formed and disposed within the substrate 400 on the bottom surface 400b. A gate insulation layer G13 may be disposed between a gate AG3 of the amplification transistor 581 and the active area 583, and a gate insulation layer G14 may be disposed between the gate SG3 and the active area 583 of the selection transistor 582. For example, in an embodiment lower surfaces of the gate insulation layers G13, G14 may directly contact the active area 583 and upper surfaces of the gate insulation layers G13, G14 may directly contact the amplification transistor 581 and the gate SG3, respectively.

The wiring layer 500 may include a plurality of wirings 551 to 556, a plurality of line insulation layers 521 to 523, and a plurality of wiring contacts 541 to 546. A description of the plurality of line insulation layers 521 to 523 is the same as the description in FIG. 6, and therefore a repeated description will be omitted for economy of description.

The plurality of wiring contacts 541 to 543 are formed on a plurality of vias of the line insulation layer 521, and each wiring contact is connected to a corresponding one of the metal layer 610, one end of the amplification transistor 581, and the amplification gate AG3. The plurality of wires 551 to 553 is disposed on the line insulation layer 521, and each of the plurality of wires 551 to 553 is connected to the plurality of wiring contacts 541 to 543 formed on the line insulation layer 521, respectively. The line insulation layer 522 may be disposed on the line insulation layer 521 to cover the plurality of wires 551 to 553. The plurality of wiring contacts 544 to 546 are formed in a plurality of vias of the line insulation layer 522, and each wiring contact may be connected to a corresponding one of the plurality of wires 551 to 553. A plurality of wires 554 to 556 are disposed on the line insulation layer 522, and each of the plurality of wires 554 to 556 is connected to each of the plurality of wiring contacts 544 to 546 formed on the line insulation layer 522. A line insulation layer 523 may be disposed on the line insulation layer 522 to cover the plurality of wires 554 to 556. The wire 554 and the wire 555 may be connected to other wires that are connected to a predetermined voltage source. For example, a predetermined voltage source may be a voltage source that supplies a voltage VDD. In an embodiment shown in FIG. 7, the wire 554 and the wire 555 are separated. However, embodiments of the present disclosure are not necessarily limited thereto and the wires 554, 555 may be branched from one wire or implemented as the same wire in some embodiments. In an embodiment, the wire 556 is connected to another wire connected to the floating diffusion 463, and may electrically connect the amplification gate AG3 and the floating diffusion 463 of the pixel area PXA4.

Since the metal layer 610 is connected to a wire supplying the voltage VDD, the N-type layers 26c and 26d are electrically connected to the voltage source supplying the voltage VDD. Electrons generated on the surface of the DTI area 25 may flow to the voltage source through the N-type layers 26c and 26d. In an embodiment in which the metal layer is formed only on the bottom surface 400b, electrons generated on the surface of the DTI area 25 may flow to the metal layer disposed on the bottom surface 400b through the N-type layers 26c and 26d. In an embodiment in which the metal layer is disposed on both the upper surface 400a and the bottom surface 400b, electrons generated on the surface of the DTI area 25 flow to the metal layer in the closest position among the upper surface 400a and bottom surface 400b through N-type layers 26c and 26d.

Hereinabove, the structure of the pixel isolation structure 2 and the pixel area including the pixel isolation structure 2 according to an embodiment have been described. Hereinafter, a manufacturing method for forming the pixel isolation structure 2 will be described according to embodiments of the present disclosure.

In the following description, a description of a process that is obvious to a person of an ordinary skill in the art as a known technology may be omitted for economy of description.

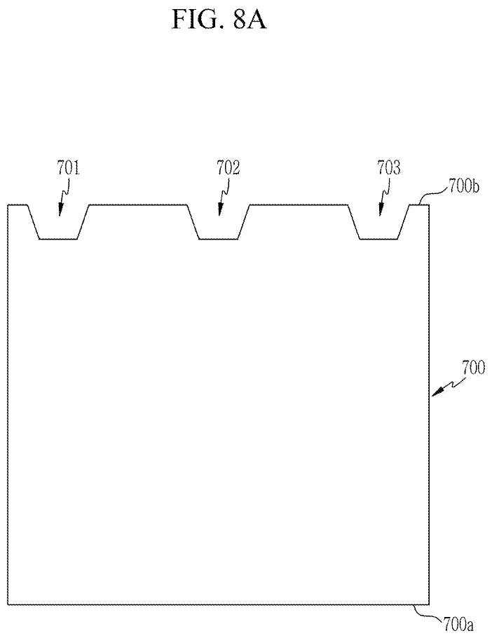

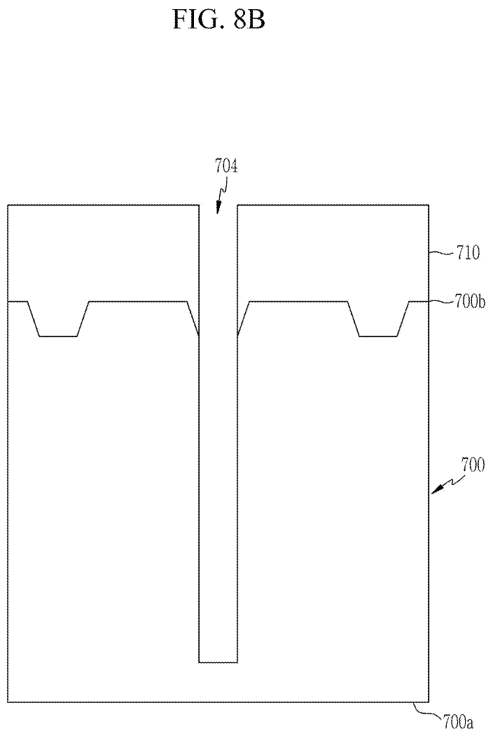

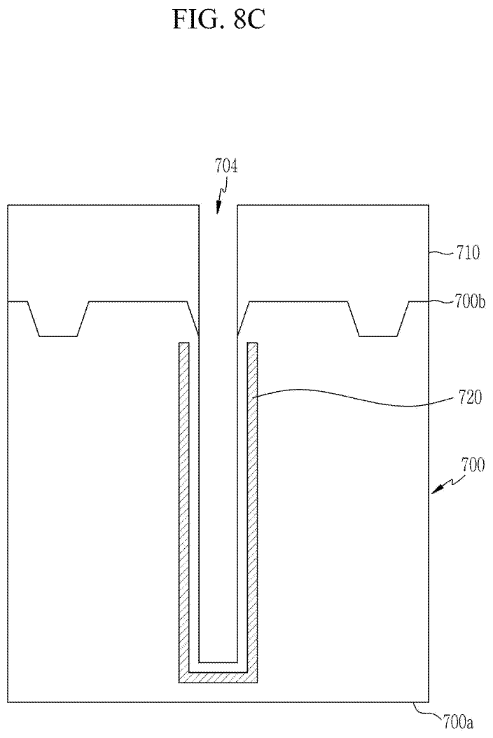

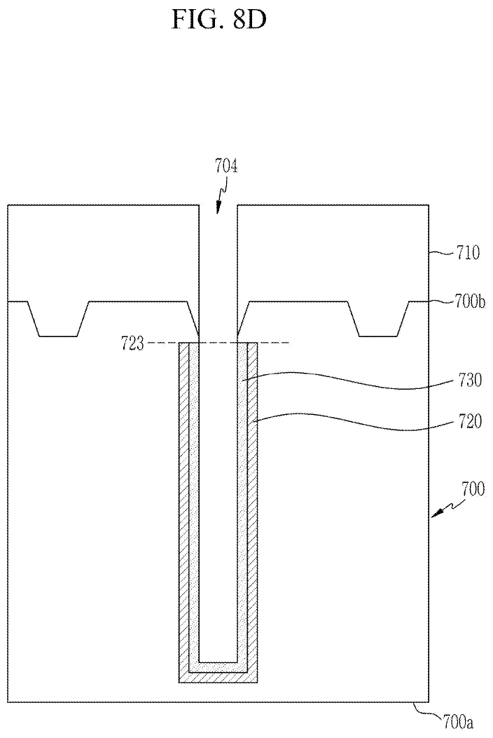

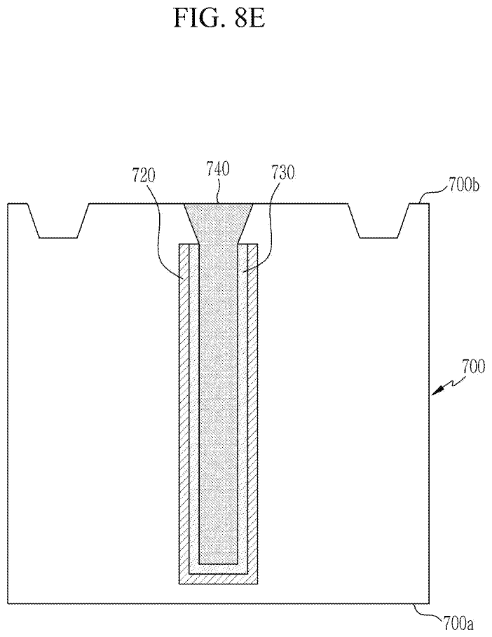

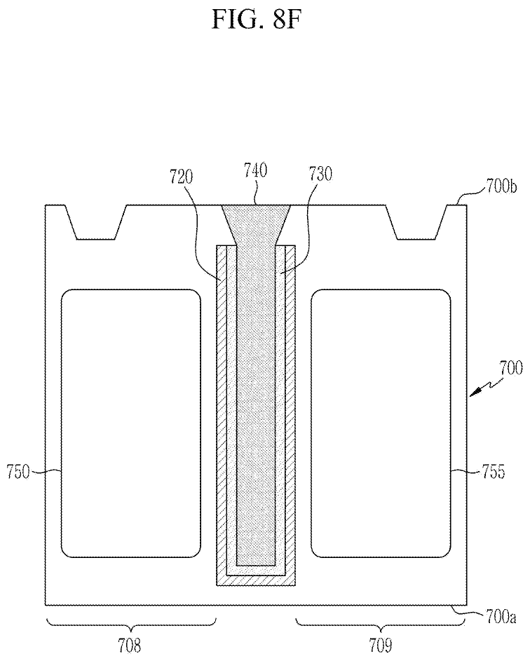

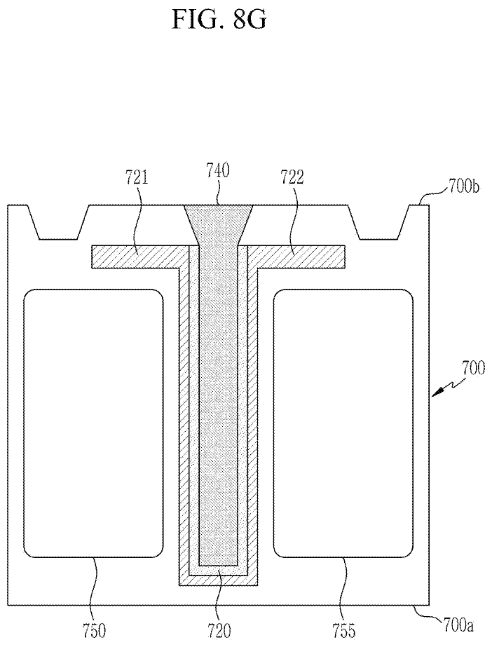

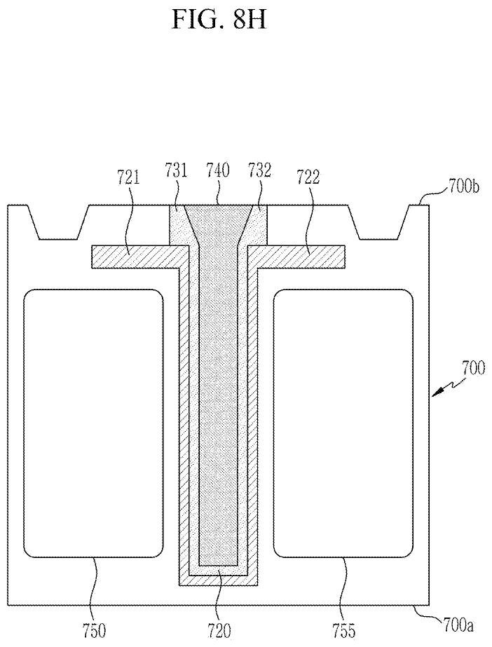

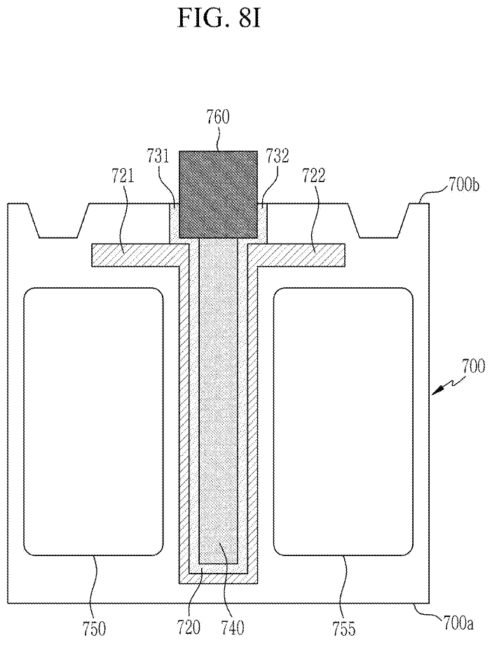

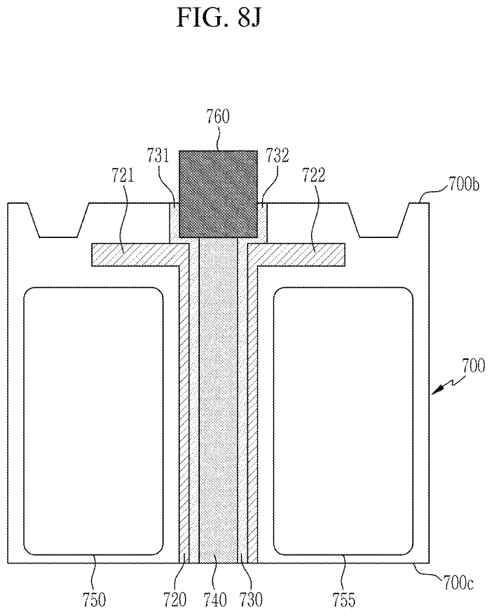

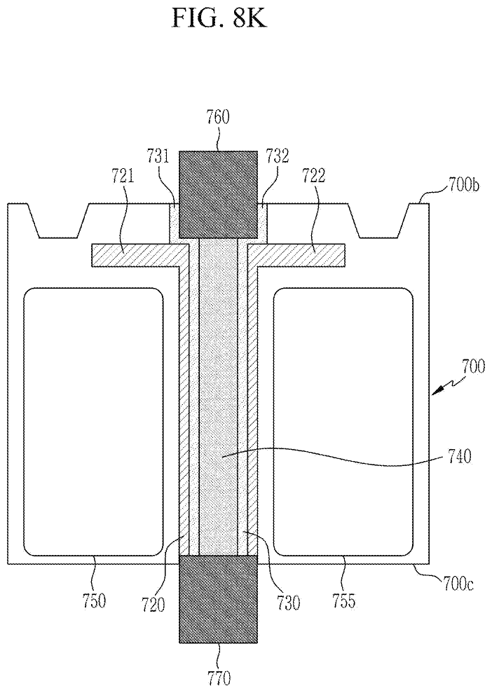

FIG. 8A to FIG. 8K show cross-sectional views of the pixel isolation structure and pixel area according to a manufacturing process of the pixel isolation structure according to embodiments of the present disclosure.

As shown in FIG. 8A, a silicon substrate 700 including a first surface 700a and a second surface 700b facing each other may be provided. The silicon substrate 700 may include the impurity of the first conductive type (e.g., p-type). The substrate 700 may include a first conductive type epitaxial layer or a first conductive type well on a first conductive type bulk silicon substrate. The second surface 700b of the substrate 700 may correspond to the bottom surface 400b of the substrate 400 shown in the above embodiments. Trenches 701, 702, and 703 may be formed on the second surface 700b of the substrate 700 and are recessed towards the first surface 700a of the substrate 700. In an embodiment, the trenches 701, 702, and 703 may be formed on the second surface 700b through an etching process using a mask pattern. The trenches 701 and 703 may be STIs for forming an element isolation pattern in the above embodiments.

As shown in FIG. 8B, a hard mask 710 is formed on (e.g., formed directly thereon) the second surface 700b, and a deep trench 704 may be formed in the substrate 700 by an etching process through the hard mask 710. It is shown in FIG. 8B that the deep trench 704 is formed in an area where the trench 702 is formed. However, embodiments of the present disclosure are not necessarily limited thereto and the deep trench 704 may be disposed in an area where no trenches 701 to 703 are formed or where trenches 701, 703 are formed in some embodiments.

As shown in FIG. 8C, a P-type layer 720 may be formed by plasma doping (PLAD) a P-type impurity into the deep trench 704. In an embodiment, the P-type impurity may include boron or the like.

As shown in FIG. 8D, after forming the P-type layer 720, an N-type layer 730 may be formed by plasma doping (PLAD) an N-type impurity into the deep trench 704. In an embodiment, the N-type impurity may include arsenic and the like. Plasma doping of the N-type impurity may be performed at an intensity lower than that of plasma doping of the P-type impurity.

The lower boundaries 64 to 65 in the above embodiment shown in embodiments of FIGS. 6-7 may be defined according to the P-type layer 720 and the N-type layer 730 formed through the process shown in FIG. 8C and FIG. 8D. The dotted line 723 shown in 8D may correspond to the lower boundaries 64 to 65.

As shown in FIG. 8E, the hard mask 710 may be removed, and a DTI area 740 may be formed by filling the deep trench 704 with an oxide-based material. In an embodiment, the hard mask 710 may be removed through an etching process. In an embodiment, after filling the deep trench 704 with an oxide material, the second surface 700b may be planarized through a chemical mechanical polishing (CMP) process.

As shown in FIG. 8F, photoelectric conversion areas 750 and 755 may be formed by doping an N-type impurity on areas 708 and 709 in the pixel area of the substrate 700, respectively. Each of the photoelectric conversion areas 750 and 755 may form a photodiode in a corresponding pixel area. In an embodiment, the n-type impurity may be implanted into the substrate 700 by gas phase doping.

As shown in FIG. 8G, PD well regions 721 and 722 may be formed by performing ion implantation of a P-type impurity in an area that is connected to the P-type layer 720 of the substrate 700 and covers at least some areas of the photoelectric conversion areas 750 and 755. The PD well regions 721 and 722 may be formed to have the pattern of the PD well region described in the previous embodiment. In FIG. 8G, the photoelectric conversion areas 750 and 755 have a shape covering (e.g., overlapping) some areas of the PD well regions 721 and 722. However, embodiments of the present disclosure are not necessarily limited thereto. In an embodiment, the PD well area may be formed from a P-type layer adjacent to both sides of the substrate shown in FIG. 8G to FIG. 8K such that all the photoelectric conversion areas 750 and 755 can be covered or areas except for the transfer gate and the channel area can be covered.

As shown in FIG. 8H, contact areas 731 and 732 may be formed by doping an N-type impurity in an area connected to (e.g., directly connected to) the N-type layer 730 of the substrate 700.

As shown in FIG. 8I, a metal layer 760 is formed in an area formed by etching the DTI area 740 and the contact areas 731 and 732, and thus the metal layer 760 may be electrically connected by contacting the N-type layer 730. The metal layer may be implemented by various methods known in the art. For example, a method of depositing or plating a metal material on an etched area may be applied.

As shown in FIG. 8J, the N-type layer 730 is exposed on one side (e.g., an upper side) of the substrate 700 by removing some areas on the first surface 700a side of the substrate 700 through the CMP process. A third surface 700c shown in FIG. 8J may correspond to the upper surface 400a in direct contact with the light transmission layer 300 in the preceding embodiments.

As shown in FIG. 8K, the metal layer 770 may be formed by depositing or plating a metal material on the N-type layer 730 and the DTI area 740 exposed on the third surface 700c. The metal layer 770 may be electrically connected by directly contacting the N-type layer 730.

Subsequent processes may include a process of forming a wiring layer on the second surface 700b and a process of forming a light transmission layer on the third surface 700c. Since the corresponding processes can be implemented with known methods, detailed descriptions are omitted for economy of description.

A leakage current flowing on the surface of the DTI area may flow to a predetermined voltage source through the N-type layer. In existing image sensors in which DTI includes polysilicon, sensitivity loss occurs optically, resulting in degradation of SNR. In contrast, since the pixel isolation structure according to an embodiment includes a DTI area implemented only with an oxide without polysilicon, optical sensitivity loss may be prevented and SNR may be increased. In addition, an embodiment may prevent photodiode degradation that may occur due to the leakage current by further including an N-type layer that may allow the leakage current that can flow in the DTI area to a voltage source.

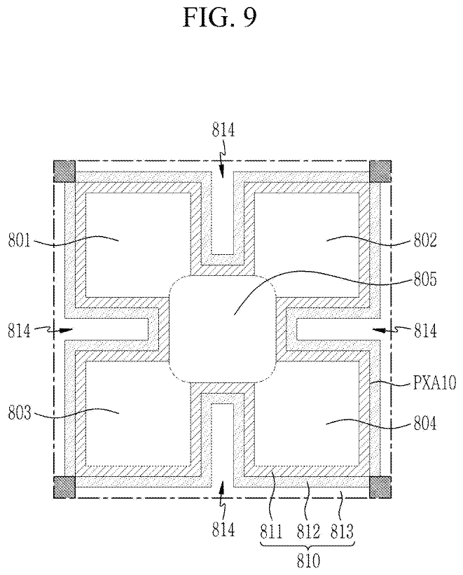

FIG. 9 is a top plan view of some of a pixel array according to an embodiment.

In FIG. 9, a top view of one pixel area PXA10 on the upper surface of the substrate facing the light transmission layer is illustrated according to an embodiment of the present disclosure.

In an embodiment, the pixel area PXA10 includes four photoelectric conversion elements 801 to 804 and a photoelectric conversion element 805 additionally formed in the middle area. The pixel area 2×2 of the embodiment described above may correspond to the pixel area PXA10 shown in an embodiment of FIG. 9.

The pixel isolation structure 810 is formed and disposed in a shape surrounding the pixel area PXA10. The pixel isolation structure 810 includes a P-type layer 811, an N-type layer 812, and a DTI area 813. First, the P-type layer 811 is formed into a shape surrounding the external circumferential surface of the pixel area PXA10, and the N-type layer 812 is formed into a shape surrounding the external circumferential surface of the P-type layer 811. In an embodiment, the DTI area 813 is formed by filling a deep trench 814 formed in a shape surrounding the pixel area PXA10 with an oxide-based material. The DTI area 813 shown in FIG. 9 is formed in a shape surrounding the external circumferential surface of the N-type layer 812. As described, compared to the pixel isolation structure 2 of an embodiment described above, the pixel isolation structure 810 is not formed in a center area of the pixel area PXA10.

The structure of the pixel area shown in FIG. 9 may reduce the amount of light blocked by the pixel isolation structure among the amount of light incident through the light transmission layer.

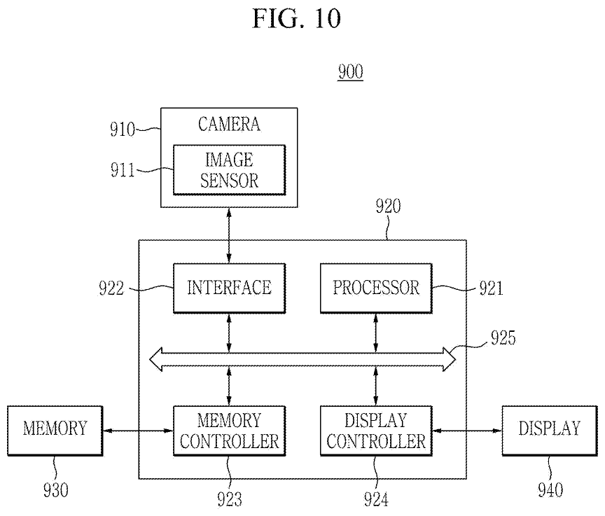

FIG. 10 is a block diagram of a computing device according to an embodiment.

Referring to FIG. 10, a computing device 900 may include a camera 910, a controller 920, a memory 930, and a display 940.

The camera 910 may include an image sensor 911. The image sensor 911 may be implemented with the image sensor described with reference to FIG. 1 to FIG. 9. The camera 910 may generate an image signal using the image sensor 911, perform image signal processing on the image signal, and output the processed image signal to the controller 920.

The controller 920 may include a processor 921. The processor 921 may control overall operations of each component of the computing device 900. In an embodiment, the processor 921 may be implemented as at least one of various processing units such as a central processing unit (CPU), an application processor (AP), and a graphic processing unit (GPU). In an embodiment, the controller 920 may be implemented as an integrated circuit or system on chip (SoC).

In an embodiment, as shown in FIG. 9, the controller 920 may further include an interface 934, a memory controller 923, a display controller 924, and a bus 925. In an embodiment, at least some of the interface 934, the memory controller 923, the display controller 924, and the bus 925 may be provided externally to the controller 920. In an embodiment, the controller 920 may further include an image signal processor.

The interface 922 may transmit an image signal received from the image sensor 911 to the memory controller 923 or the display controller 924 through the bus 925.

The memory 930 may store various data and instructions. The memory controller 923 may control transmission of data or instructions to and from the memory 930.

The display controller 924 transmits data to be displayed on the display 940 to the display 940 under the control of the processor 921, and the display 940 may display a screen according to the received data. In an embodiment, the display 940 may further include a touch screen. The touch screen may transmit a user input that can control the operation of the computing device 900 to the controller 920. In an embodiment, the user input may be generated in response to a user touching (or being in proximity to) the touch screen.

The bus 925 may provide a communication function between constituent elements of the controller 920. The bus 925 may include at least one type of bus according to a communication protocol between constituent elements.

While the present disclosure has been described in connection with embodiments thereof, it is to be understood that the present disclosure is not necessarily limited to the described embodiments. On the contrary, it is intended to cover various modifications and equivalent arrangements included within the spirit and scope of the present disclosure.

What is claimed is:

1. An image sensor comprising a substrate including a plurality of pixel areas and a pixel isolation structure isolating each of the plurality of pixel areas,
wherein the pixel isolation structure comprises:
a deep trench isolation (DTI) area disposed between two adjacent pixel areas among the plurality of pixel areas;
an N-type layer disposed in contact with the DTI area and positioned between the DTI area and the plurality of pixel areas; and a P-type layer disposed in contact with the plurality of pixel areas and positioned between the DTI area and the plurality of pixel areas.

2. The image sensor of claim 1, wherein
the DTI area includes an oxide-based material disposed in a deep trench defined in the substrate.

3. The image sensor of claim 1, further comprising a metal layer electrically connected with the N-type layer and disposed on a first surface of the substrate, wherein the metal layer and the N-type layer directly contact each other.

4. The image sensor of claim 3, wherein the N-type layer comprises a contact area that is arranged to extend to the first surface of the substrate and directly contacts a side surface of the metal layer.

5. The image sensor of claim 3, wherein:
a first side of the N-type layer comprises an area directly contacting the DTI area and an opposite second side of the N-type layer comprises an area directly contacting the P-type layer; and
the N-type layer comprises a contact area that is electrically connected to the metal layer by directly contacting a portion of a side surface of the metal layer.

6. The image sensor of claim 3, further comprising a metal layer that is electrically connected to the N-type layer by directly contacting the N-type layer, the metal layer is disposed on a second surface that is opposite to the first surface of the substrate.

7. The image sensor of claim 3, further comprising a wiring layer disposed on the first surface of the substrate,
wherein the wiring layer comprises at least one contact and at least one wire that are connected to the metal layer, and
the metal layer is connected to a predetermined voltage source through the at least one contact and the at least one wire.

8. The image sensor of claim 1, wherein:
each of the plurality of pixel areas comprises a photoelectric conversion area generating a charge according to incident light; and
the P-type layer comprises a PD well that extends in a direction that is orthogonal to a depth direction of the substrate and is positioned between the photoelectric conversion area in each pixel area and a first surface of the substrate.

9. The image sensor of claim 8, wherein each of the plurality of pixel areas further comprises:
a floating diffusion; and
a transfer gate that provides an on-voltage for forming a channel between the photoelectric conversion area and the floating diffusion to the photoelectric conversion area,
wherein the PD well is not disposed in a first area where a channel between the floating diffusion and the photoelectric conversion area is disposed and a second area where the transfer gate is disposed.

10. An image sensor comprising a substrate including a plurality of pixel areas and a pixel isolation structure isolating each of the plurality of pixel areas,
wherein the pixel isolation structure comprises:
a first P-type layer surrounding a first pixel area among the plurality of pixel areas;
a second P-type layer surrounding a second pixel area adjacent to the first pixel area in a first direction among the plurality of pixel areas;
a first N-type layer and a second N-type layer surrounding the first and second P-type layers, respectively; and
a DTI area that is disposed between the first N-type layer and the second N-type layer.

11. The image sensor of claim 10, wherein
the DTI area includes an oxide-based material disposed in a deep trench defined in the substrate.

12. The image sensor of claim 10, further comprising:
a third pixel area disposed adjacent to the first pixel area in a second direction crossing the first direction;
a fourth pixel area disposed adjacent to the second pixel area in the second direction;
a metal layer disposed adjacent to a corner area of each of the first pixel area, the second pixel area, the third pixel area and the fourth pixel area, and is electrically connected to the first N-type layer and the second N-type layer.

13. The image sensor of claim 12, wherein:
a portion of the first N-type layer is exposed in a first surface of the substrate and directly contacts the metal layer; and
a portion of the second N-type layer is exposed in the first surface of the substrate and directly contacts the metal layer.

14. The image sensor of claim 12, further comprising:
a third P-type layer surrounding the third pixel area;
a fourth P-type layer surrounding the fourth pixel area; and
a third N-type layer and a fourth N-type layer that surround the third and fourth P-type layers, respectively,
wherein the metal layer is electrically connected to the third N-type layer and the fourth N-type layer.

15. The image sensor of claim 14, wherein:
a portion of the third N-type layer is exposed in a first surface of the substrate and directly contacts the metal layer; and
a portion of the fourth N-type layer is exposed in the first surface of the substrate and directly contacts the metal layer.

16. The image sensor of claim 12, further comprising a wiring layer disposed on a first surface of the substrate,
wherein the wiring layer comprises at least one contact and at least one wire connected to the metal layer, and
the metal layer is connected to a predetermined voltage source through the at least one contact and the at least one wire.

17. The image sensor of claim 10, further comprising a light transmission layer disposed on a first surface of the substrate.

18. An image sensor manufacturing method comprising:
forming a hard mask on a first side of a substrate, and forming a first trench in the substrate through an etching process using the hard mask;
forming a P-type layer by plasma doping (PLAD) a P-type impurity into the first trench;
forming an N-type layer by plasma doping (PLAD) an N-type impurity into the first trench;
removing the hard mask, and forming a DTI area by filling an oxide-based material in the first trench; and
forming a photoelectric conversion area by doping a pixel area of the substrate with an N-type impurity.

19. The image sensor manufacturing method of claim 18, further comprising:
forming a PD well area by performing ion implantation of a P-type impurity in an area that is directly connected to the P-type layer of the substrate and covers at least a portion of the photoelectric conversion area; and
forming a contact area by doping an area directly connected to the N-type layer of the substrate with an N-type impurity.

20. The image sensor manufacturing method of claim 19, further comprising forming a metal layer in an area formed by etching the DTI area and the contact area,
wherein the metal layer is electrically connected to the N-type layer by directly contacting the N-type layer.
